(19) United States
(12) Patent Application Publication
(10) Pub. No.: US 2010/0320598 A1
(43) Pub. Date: Dec. 23, 2010

(54) SEMICONDUCTOR DEVICE AND FABRICATION METHOD THEREOF

(75) Inventors: Kei Murayama, Nagano-shi (JP); Mitsuhiro Aizawa, Nagano-shi (JP)

Correspondence Address: IPUSA, P.L.L.C, 1054 31ST STREET, N.W., Suite 400, Washington, DC, 20007, US

(73) Assignee: SHINKO ELECTRIC INDUSTRIES CO., LTD.

(21) Appl. No.: 12/813,570

(22) Filed: Jun. 11, 2010

(30) Foreign Application Priority Data
Jun. 18, 2009 (JP) 2009-145429
Jun. 9, 2010 (JP) 2010-132157

(51) Int. Cl. H01L 23/522; H01L 23/538; H01L 21/60

(52) U.S. Cl. 257/737; 438/109; 257/777; 257/686; 257/784; 257/E21.499; 257/E21.506; 257/E23.142; 257/E23.169

(57) ABSTRACT

A semiconductor device includes a stacked chip structure provided on a board and made up of semiconductor chips that are stacked via insulators. Each semiconductor chip has an integrated circuit surface, pads provided on the integrated circuit surface, and conductive connecting members having a wave shape with first ends electrically connected to the pads, and second ends extending outwardly from the at least one edge part and electrically connected to the connection terminals on the board.

### CROSS-REFERENCE TO RELATED APPLICATIONS

This application is based upon and claims the benefit of priority of the prior Japanese Patent Applications No. 2009-145429 filed on Jun. 18, 2009 and No. 2010-132157 filed on Jun. 9, 2010, the entire contents of which are incorporated herein by reference.

### BACKGROUND OF THE INVENTION

1. Field of the Invention

The present invention generally relates to semiconductor devices and fabrication methods thereof, and more particularly to a semiconductor device having a plurality of semiconductor chips that are stacked, and to a fabrication method thereof.

2. Description of the Related Art

A stacked semiconductor device having a plurality of semiconductor chips that are stacked is also referred to as a stacked package. The stacked semiconductor device realizes predetermined functions by a combination of existing semiconductor chips, without newly developing a semiconductor chip exclusively for realizing the predetermined functions. An example of the stacked semiconductor device is proposed in a Japanese Laid-Open Patent Publication No. 2009-27041, for example.

FIGS. 1A and 1B are diagrams for explaining an example of a conventional stacked semiconductor device. FIG. 1A illustrates a side view of a stacked semiconductor device 100 having three (3) semiconductor chips 101 that are stacked via bonding layers 102 to thereby form a stacked chip structure 103. Metal wires 105 are connected to electrode terminals 104 on the semiconductor chips 101, and the metal wires 105 are electrically connected by a conductive (or conductor) paste 106 arranged linearly on side surfaces of the semiconductor chips 101, in order to achieve desired electrical connections in the stacked chip structure 103.

However, when providing the metal wires 105 on the semiconductor chip 101, it is necessary to carry out a process that includes preparing a metal film 107, and wire-bonding the metal wires 105 thereon, as illustrated in FIG. 1B. FIG. 1B illustrates a side view, on an enlarged scale, for explaining the wire-bonding of the metal wires 105.

In addition, when making the electrical connection using the conductive paste 106, it is necessary to carry out a process that includes coating and connecting using a transfer wire 108 applied with a conductive paste 106a as illustrated in FIG. 1A.

Because of the above described structure of the connecting part using the conductive paste, the electrical characteristics of the stacked chip structure may be difficult to improve. Further, in a case where the stacked semiconductor device is connected to a wiring board or a circuit board, it may be difficult to improve the mechanical characteristics of the stacked chip structure and absorb an internal stress that is generated between the wiring or circuit board and the connecting part caused by a difference between a coefficient of thermal expansion of the wiring or circuit board and a coefficient of thermal expansion of the connecting part. Therefore, it was conventionally difficult to improve the electrical characteristics and mechanical characteristics of the stacked chip structure and to simplify the fabrication process of the stacked semiconductor device.

### SUMMARY OF THE INVENTION

Accordingly, it is a general object of the present invention to provide a novel and useful semiconductor device and fabrication method thereof, in which the problems described above are suppressed.

Another and more specific object of the present invention is to provide a semiconductor device and a fabrication method thereof, suited for improving the electrical characteristics and the mechanical characteristics of the stacked chip structure of the stacked semiconductor device, and capable of improving the productivity or production capability of the stacked chip structure in order to simplify the fabrication process of the stacked semiconductor device.

According to one aspect of the present invention, there is provided a semiconductor device comprising a board having a mounting surface and a plurality of connection terminals provided on the mounting surface; and a stacked chip structure provided on the board and including a plurality of semiconductor chips that are stacked via insulators, wherein the semiconductor chips in the stacked chip structure include semiconductor chips comprising an integrated circuit surface; a plurality of pads provided on the integrated circuit surface along at least one edge part of the integrated circuit surface; and a plurality of conductive connecting members having a wave shape with first ends electrically connected to the pads, and second ends extending outwardly from the at least one edge part and electrically connected to the connection terminals on the board, wherein the conductive connecting members of at least one of the semiconductor chips have a length different from that of the conductive connecting members of another semiconductor chip in the stacked chip structure, and the conductive connecting members are formed by bonding wires, and the second ends of the conductive connecting members extending from the semiconductor chips in the stacked chip structure are aligned on the connection terminals on the board.

According to one aspect of the present invention, there is provided a semiconductor device fabrication method comprising electrically connecting first ends of conductive connecting members on pads on a semiconductor chip; stacking a plurality of semiconductor chips via insulators to form a stacked chip structure; and mounting the stacked chip structure on a mounting surface of a board by electrically connecting second ends of the conductive connecting members to connection terminals on the mounting surface, wherein the conductive connecting members have a wave shape, the conductive connecting members of at least one of the semiconductor chips have a length different from that of the conductive connecting members of another semiconductor chip in the stacked chip structure, and the conductive connecting members are formed by bonding wires, and said mounting aligns the second ends of the conductive connecting members extending from the semiconductor chips in the stacked chip structure on the connection terminals on the board.

Other objects and further features of the present invention will be apparent from the following detailed description when read in conjunction with the accompanying drawings.

### BRIEF DESCRIPTION OF THE DRAWINGS

FIGS. 1A and 1B are diagrams for explaining an example of a conventional stacked semiconductor device;

FIG. 2 is a flow chart for explaining a semiconductor device fabrication method in a first embodiment of the present invention;

FIGS. 3A and 3B are cross sectional views for explaining the semiconductor device fabrication method in the first embodiment;

FIGS. 4A through 4D are cross sectional views, on an enlarged scale, for explaining various shapes of bonding wires;

FIG. 5 is a cross sectional view for explaining a state where an insulator resin is coated on an integrated circuit surface of a semiconductor chip having bonding wires;

FIG. 6 is a cross sectional view, on an enlarged scale, for explaining a state where the semiconductor chips having the bonding wires and the insulator resin are stacked and mounted on a wiring board;

FIG. 7 is a cross sectional view, on an enlarged scale, for explaining a state where ends of the bonding wires of the stacked semiconductor chips are connected on the wiring board;

FIG. 8 is a cross sectional view, on an enlarged scale, for explaining the semiconductor device fabrication method in a modification of the first embodiment;

FIGS. 9A through 9D are diagrams for explaining a bonding tool used in the semiconductor device fabrication method in the first embodiment;

FIG. 10 is a cross sectional view, on an enlarged scale, for explaining a state where a resin encapsulation is carried out with respect to a completed stacked chip structure;

FIG. 11 is a cross sectional view, on an enlarged scale, for explaining the semiconductor device fabrication method in a second embodiment of the present invention;

FIG. 12 is a cross sectional view, on an enlarged scale, for explaining the semiconductor device fabrication method in a third embodiment of the present invention;

FIG. 13 is a cross sectional view, on an enlarged scale, for explaining the semiconductor device fabrication method in a modification of the third embodiment;

FIG. 14 is a cross sectional view, on an enlarged scale, for explaining the semiconductor device fabrication method in a fourth embodiment of the present invention;

FIG. 15 is a cross sectional view, on an enlarged scale, for explaining a state where ends of the bonding wires of the stacked semiconductor chips are connected on the wiring board in a fifth embodiment of the present invention; and

FIG. 16 is a cross sectional view, on an enlarged scale, for explaining the semiconductor device fabrication method in a sixth embodiment of the present invention.

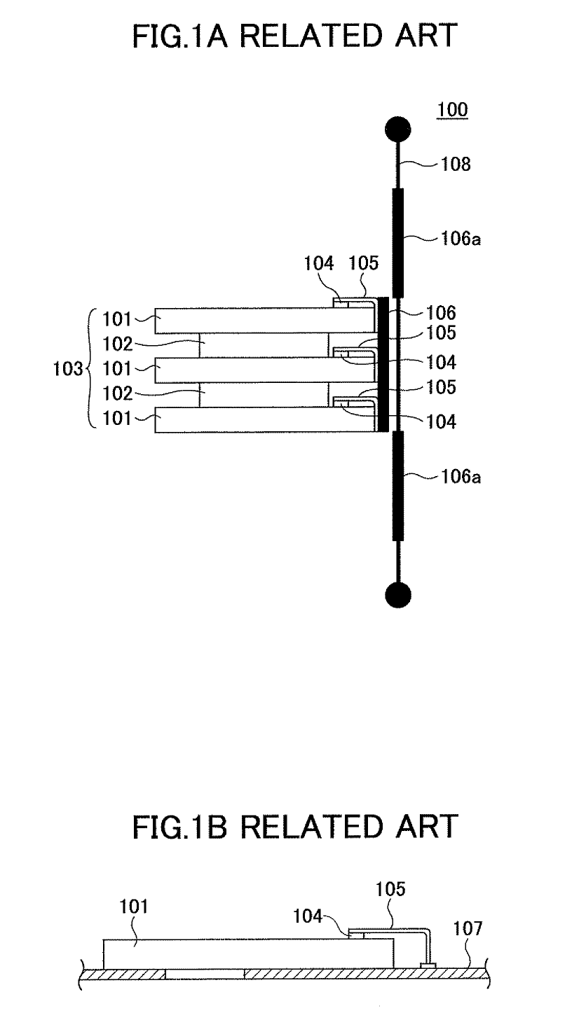

### DESCRIPTION OF THE PREFERRED EMBODIMENTS

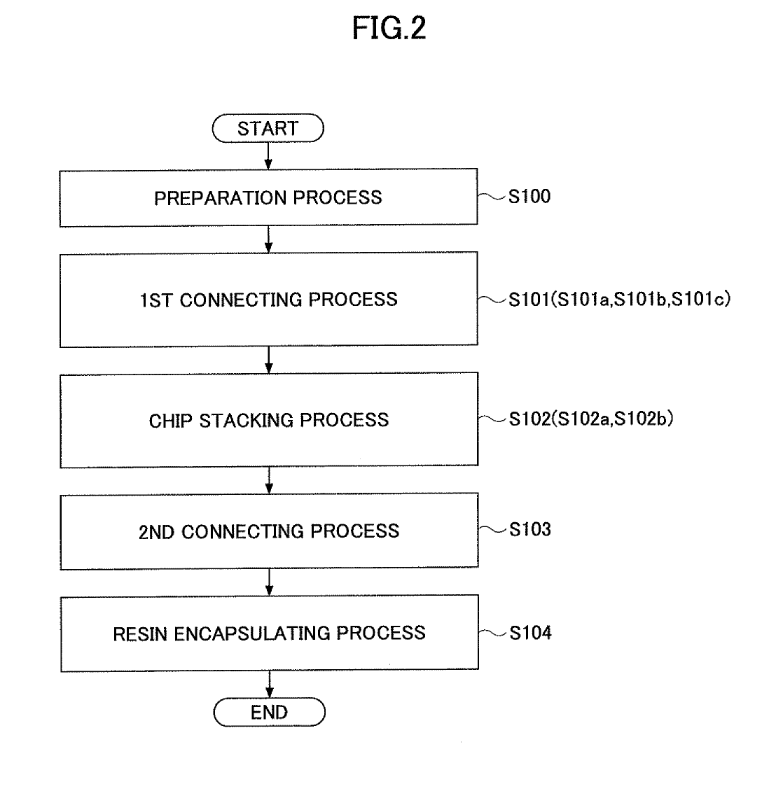

A description will be given of a semiconductor device and a semiconductor device fabrication method in embodiments of the present invention, by referring to FIG. 2 and subsequent figures.

### First Embodiment

FIG. 2 is a flow chart for explaining the semiconductor device fabrication method in a first embodiment of the present invention. The semiconductor device fabrication method illustrated in FIG. 2 includes a preparation step (or process) S100, a first connecting step (or process) S101, a chip stacking step (or process) S102, a second connecting step (or process) S103, and a resin encapsulating step (or process) S104.

In the step S100, a semiconductor wafer having an outer diameter of any one of 6 inches, 8 inches and 12 inches, for example, is prepared. The semiconductor wafer is subjected to a thinning (or thickness reducing) process such as back grinding, and to a dicing process to dice the semiconductor wafer into a plurality of semiconductor chips. The semiconductor chips obtained by the dicing process is placed on a dicing tape.

The step S101 includes steps S101a and S101b. In the step S101a, the individual semiconductor chips prepared in the step S100 are picked up from the dicing tape and placed on a provisional bonding film. For example, the provisional bonding film may be made of a material such as polyester. In the step S101b, conductive connecting members are electrically connected (or bonded) to pads on the semiconductor chip. For example, bonding wires are used as the conductive connecting members.

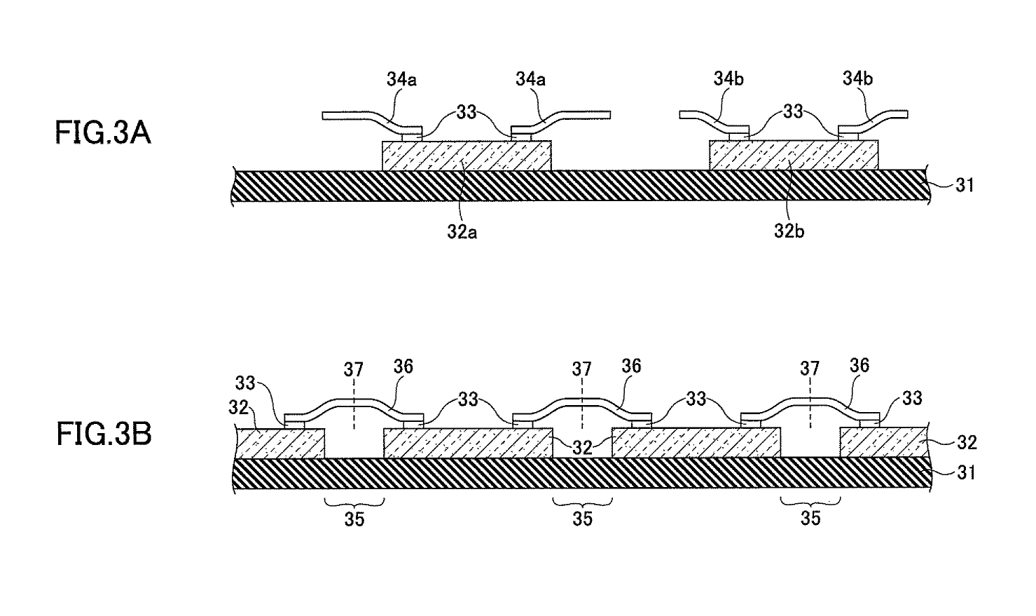

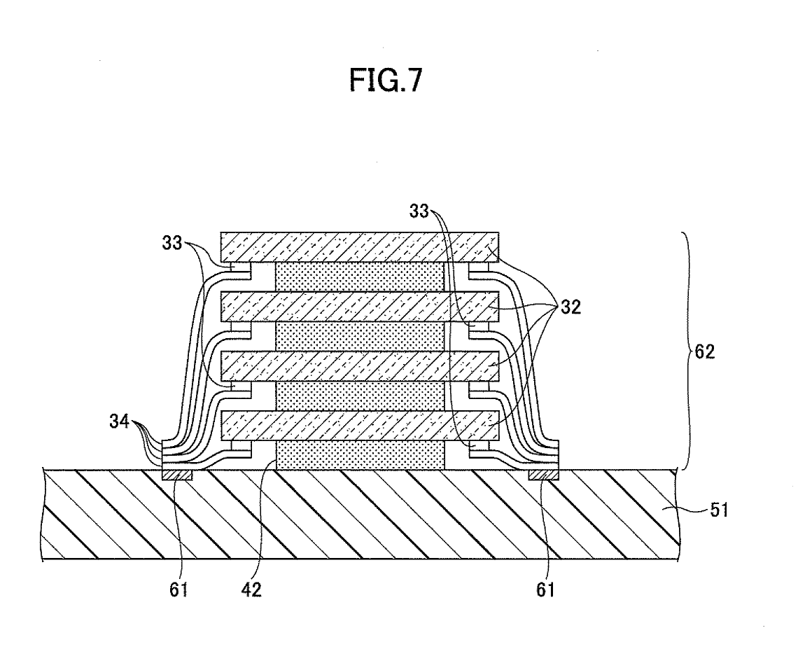

FIGS. 3A and 32 are cross sectional views for explaining the semiconductor device fabrication method in the first embodiment. FIG. 3A illustrates a state where bonding wires 34a and 34b are connected to pads 33 on semiconductor chips 32a and 32b that are placed on a provisional bonding film 31. The bonding wires 34a and 34b are cut to different lengths depending on design specifications of a stacked chip structure that is to be formed by the semiconductor chips 32a and 32b. For example, the bonding wires 34a and 34b may be cut using a capillary and clamp mechanism of a wire bonding apparatus (not illustrated). In FIG. 3A, the length of the bonding wire 34a is set longer than the length of the bonding wire 34b, because the length of the bonding wire 34a of the semiconductor chip 32a is set longer than the length of the bonding wire 34b of the semiconductor chip 32b located below the semiconductor chip 32a in the stacked chip structure. By setting the bonding wires 34a and 34b to different lengths, it becomes possible to align or match ends of the bonding wires 34a and 34b when the second connecting step S103 is completed as will be described later in conjunction with FIG. 7. The amount of deformation of the bonding wires 34a and 34b that are deformed when connecting the stacked chip structure to a wiring board by thermo-compression bonding or the like may also be taken into consideration in advance when setting the lengths of the bonding wires 34a and 34b.

The bonding wires 34a and 34b may be made of a material such as gold (Au), copper (Cu), alloys of such metals, and the like, for example. In addition, the bonding wires 34a and 34b may have a diameter in a range of 15 μm to 30 μm, for example.

The semiconductor chips 32a and 32b may have a thickness in a range of 40 μm to 50 μm, for example, but the thickness may be appropriately selected depending on the functions, the usage and the like of the semiconductor chips 32a and 32b.

The bonding wires 34a and 34b illustrated in FIG. 3A may be formed by a method described hereunder in conjunction with FIG. 3B. According to this method, pads 33 of adjacent semiconductor chips 32 that are separated by a gap 35 are connected by a conductive connecting member 36 that is shaped to traverse the adjacent semiconductor chips 32 as illustrated in FIG. 3B. When fabricating a relatively large number of stacked chip structures, the conductive connecting members 36 are cut at intermediate points 37 as illustrated in FIG. 3B in order to reduce the number of cuts and to efficiently fabricate identical semiconductor chips 32 having identical stacking locations in each stacked chip structure.

The step S101 may further include a step S101c to shape the bonding wire 34 (34a or 34b), that is the conductive connecting member 36 after being cut. By shaping the bonding wire 34 into an S-shape or a wave shape formed by consecutive S-shapes immediately after connecting the bonding wire 34 to the pad 33, it becomes possible to more smoothly connect the bonding wire 34 to the wiring board in the step S103 which will be described later. For example, the semiconductor device may be fabricated efficiently while including the step S101c, if operation elements for shaping the bonding wire 34, such as a reverse motion, is built into a control system when utilizing a loop control function of the wire bonding apparatus, for example.

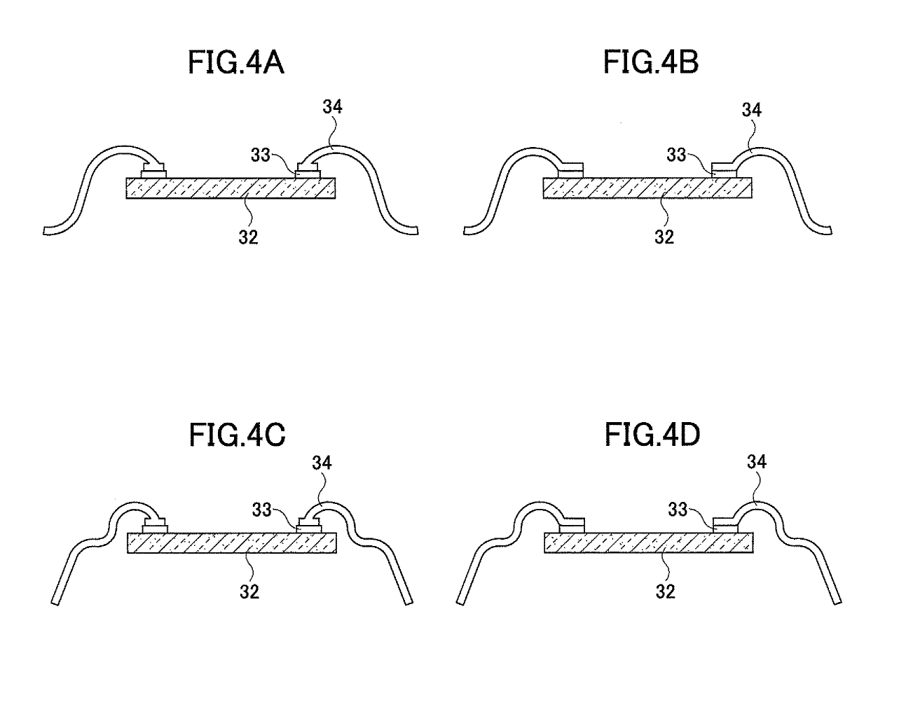

FIGS. 4A through 4D are cross sectional views, on an enlarged scale, for explaining various shapes of bonding wires.

FIG. 4A illustrates a state where the bonding wire 34 after being connected to the pad 33 is shaped into the S-shape. FIG. 4B illustrates a state where a portion of the bonding wire 34 connected to the pad 33 extends parallel to an integrated circuit surface (that is, upper surface) of the semiconductor chip 32. FIG. 4C illustrates a state where the bonding wire 34 is shaped to have two (2) transition points in the form of consecutive S-shapes. FIG. 4D illustrates a state where the bonding wire 34 is shaped to have two (2) transition points in the form of consecutive S-shapes, similar to the shapes illustrated in FIG. 4C, and a portion of the bonding wire 34 connected to the pad 33 extends parallel to an integrated circuit surface (that is, upper surface) of the semiconductor chip 32, similar to the shapes illustrated in FIG. 4B.

Of course, the length of the bonding wire 34 in each of FIGS. 4A through 4D may be appropriately set depending on the location of the semiconductor chip 32 in the stacked chip structure and the amount of deformation of the bonding wire 34 that is deformed when connecting the stacked chip structure to the wiring board by the thermo-compression bonding or the like.

By carrying out the step S101c to shape the bonding wire 34 as illustrated in any one of FIGS. 4A through 4D, it becomes possible to more smoothly connect the bonding wire 34 to the wiring board in the step S103 which will be described later. In addition, even if an internal stress is generated between the pads 33 of the semiconductor chip 32 and the wiring board due to a difference between a coefficient of thermal expansion of the pads 33 of the semiconductor chip 32 and a coefficient of thermal expansion of the wiring board, it is possible to absorb the internal stress by the bonding wire 34 that is shaped to sufficiently absorb the internal stress by undergoing suitable resilient deformation. Therefore, it is possible to improve the electrical characteristics and mechanical characteristics of the stacked chip structure and to simplify the fabrication process of the stacked semiconductor device.

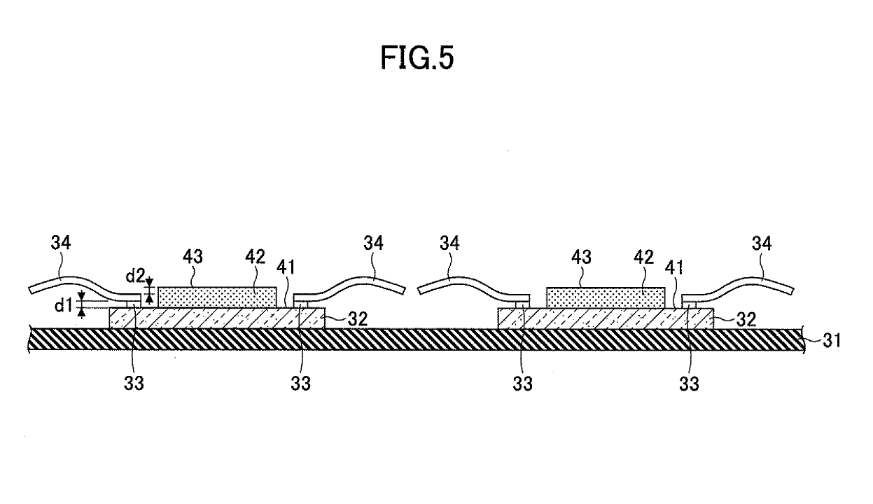

FIG. 5 is a cross sectional view for explaining a state where an insulator resin 42 is coated on an integrated circuit surface 41 of the semiconductor chip 32 having the bonding wires 34 described above.

The step S102 includes steps S102a and 102b. In the step S102a, the insulator resin 42 is coated on the integrated circuit surface 41 of the semiconductor chip 32 having the bonding wires 34, as illustrated in FIG. 5. In the step S102b, the semiconductor chips 32 illustrated in FIG. 5 are stacked, as will be described later.

The bonding wire 34 must maintain its shape in order to prevent the bonding wire 34 from contacting the surface or the edge part of the semiconductor chip 32 when the semiconductor chips 32 are stacked. However, the contact between the bonding wire 34 and the surface or the edge part of the semiconductor chip 32 does not introduce problems if a separate step (or process) is carried out to protect and insulate the surface or the edge part of the semiconductor chip 32 by forming thereon an insulator layer made of silicon dioxide (SiO₂) or the like, for example.

In FIG. 5, the lower surface portion of the bonding wire 34 connecting to the pad 33 is a distance d1 from the integrated circuit surface 41 of the semiconductor chip 32, and this distance d1 is 10 μm, for example. In addition, the upper surface portion of the bonding wire 34 connecting to the pad 33 is a distance d2 from an upper surface 43 of the insulator resin 42, and this distance d2 is 10 μm, for example.

The insulator resin 42 may be formed by a known method including screen printing, spin-coating, and resin film or sheet adhesion (or bonding). The insulator resin 42 may be made of an epoxy resin or the like, for example. It is also possible to use a thermoplastic resin for the insulator resin 42 and carry out a heating process, in order to provisionally cure the insulator resin 42 to prepare for the next step S102b. The provisional curing temperature may be 125° C. for the screen printing, 125° C. for the spin-coating, and 80° C. for the resin film or sheet adhesion (or bonding), for example.

The step S102a may be carried out before the step S101b described above. In this case, it is possible to more easily coat the insulator resin 42 on the semiconductor chip 32 because the bonding wires 34 do not interfere with each other.

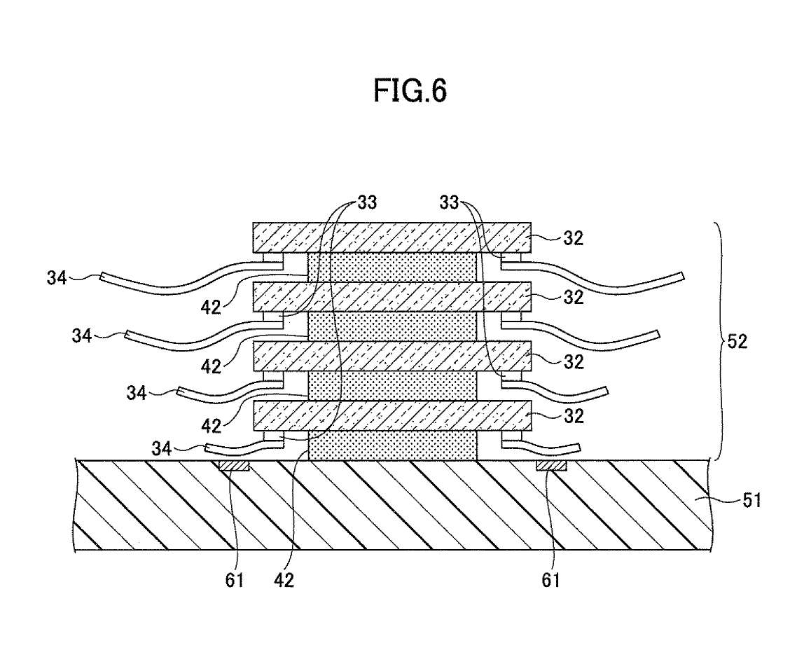

FIG. 6 is a cross sectional view, on an enlarged scale, for explaining a state where the semiconductor chips 32 having the bonding wires 34 and the insulator resin 42 are stacked and mounted on a mounting surface of a wiring board (or circuit board) 51. In the step S102b, the semiconductor chips 32 on the provisional bonding film 31 illustrated in FIG. 5 are picked up and stacked to form a stacked chip structure 52 illustrated in FIG. 6.

The stacked chip structure 52 may be formed by a die mount apparatus (not illustrated) or a flip-chip mounting apparatus (not illustrated), which aligns and fixes the semiconductor chips 32. In FIG. 6, the integrated circuit surface 41 of each semiconductor chip 32 faces the mounting surface (or upper surface) of the wiring board 51, that is, each semiconductor chip 32 is mounted upside down so that the integrated circuit surface 41 faces downwards. Hence, when picking up the semiconductor chips 32 on the provisional bonding film 31 illustrated in FIG. 5, the semiconductor chips 32 are turned upside down before being stacked. The stacked chip structure 52 may be fixed to the wiring board 51 via the insulator resin 42 of the lowermost semiconductor chip 32, by carrying out a heating process at a temperature of 150° C. for 30 minutes, for example.

FIG. 7 is a cross sectional view, on an enlarged scale, for explaining a state where ends of the bonding wires 34 of the stacked semiconductor chips 32 are connected to connection terminals 61 on the wiring board 51, to thereby form a completed stacked chip structure 62.

In the step S103, the ends of the wave-shaped bonding wires 34 extending outwardly from the stacked semiconductor chips 32 in FIG. 6 are electrically connected (or bonded) to the corresponding connection terminals 61 on the wiring board 51 by a thereto-compression bonding or the like using the wire bonding apparatus, for example, to obtain the completed stacked chip structure 62 illustrated in FIG. 7. Because the bonding wires 34 are shaped into the wave shape by the step S101c after the step S101b, the operation of electrically connecting (or bonding) the ends of the bonding wires 34 to the corresponding connection terminals 61 can be carried out smoothly.

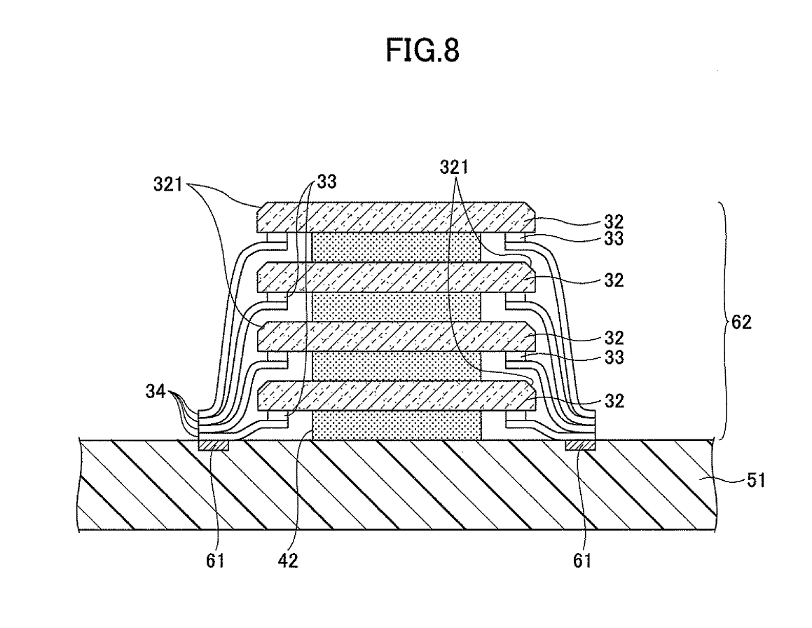

FIG. 8 is a cross sectional view, on an enlarged scale, for explaining the semiconductor device fabrication method in a modification of the first embodiment. In FIG. 8, those parts that are the same as those corresponding parts in FIG. 7 are designated by the same reference numerals, and a description thereof will be omitted.

In this modification, the surface of the semiconductor chip 32 opposite to the integrated circuit surface 41 has a chamfered part (or a sloping part) 321 along at least the edge parts where the bonding wires 34 extend outwards. In other words, the chamfered part 321 is provided along at least the edge part of the surface opposite to the integrated circuit surface 41 where the pads 33 are provided. For example, the bonding wire 34 extending generally downwards from the uppermost semiconductor chip 32 in FIG. 8 has a sufficient clearance from the surface and the edge part of the semiconductor chip 32 located immediately below, due to the provision of the chamfered part 321. As a result, it is possible to more positively prevent the bonding wire 34 from making contact with the surface or the edge part of the semiconductor chip 32. For example, the chamfered part 321 may be formed when dicing the semiconductor wafer into the semiconductor chips 32 by carrying out a bevel cutting process using a dicing apparatus (not illustrated).

It is not essential for the uppermost semiconductor chip 32 in FIG. 8 to have the chamfered part 321 because the bonding wires 34 extend downwardly to make the connection to the connection terminals 61. Further, the chamfered part 321 may be replaced by a rounded part.

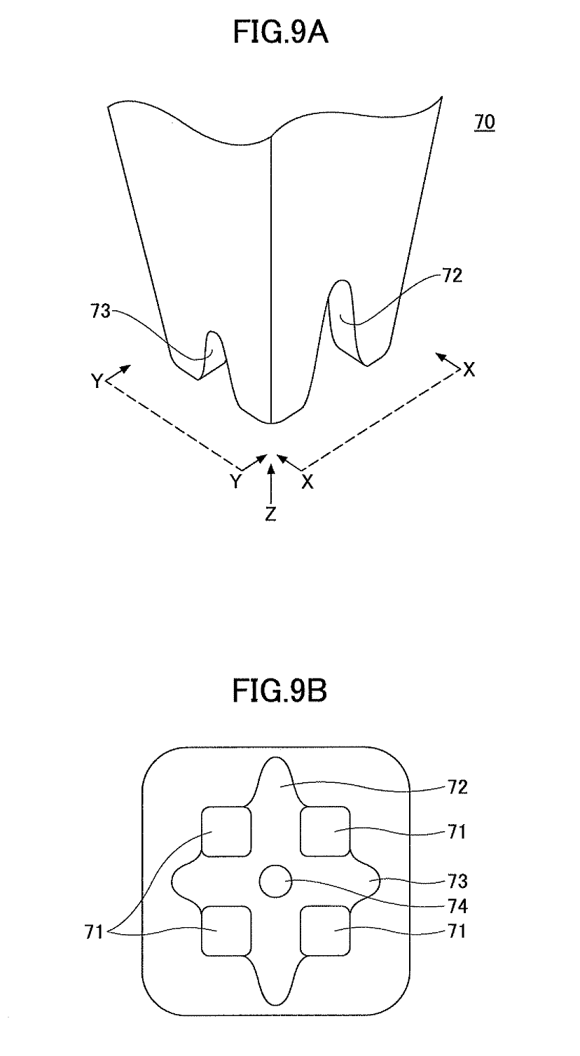

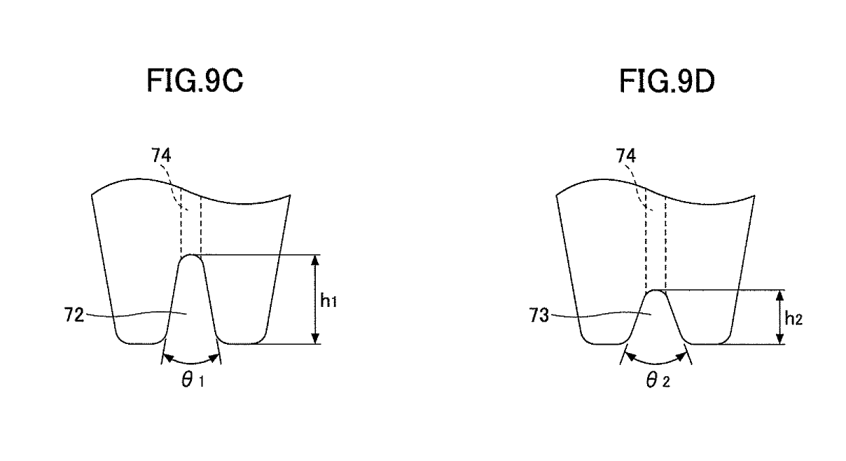

FIGS. 9A through 9D are diagrams for explaining a bonding tool 70 of the wire bonding apparatus used in the semiconductor device fabrication method in the first embodiment. FIG. 9A is a perspective view of the bonding tool 70, and FIG. 9B is a bottom view of the bonding tool 70 viewed in a direction Z in FIG. 9A. FIG. 9C is a side view of the bonding tool 70 viewed in a direction X-X in FIG. 9A, and FIG. 9D is a side view of the bonding tool 70 viewed in a direction Y-Y in FIG. 9A.

The bonding tool 70 in FIG. 9B includes a center penetration hole 74 through which the bonding wires 34 may pass, and the bonding tool 70 has a capillary function. The bonding tool 70 further includes a bottom surface 71, and grooves 72 and 73. The bottom surface 71 makes contact with the upper surface of the wiring board 51 illustrated in FIG. 7. Depths h1 and h2 of the grooves 72 and 73 illustrated in FIGS. 9C and 9D provide a function of applying appropriate pressing force, heat and vibration with respect to the bonding wires 34 that are overlapped and bonded. By selectively using grooves 72 and 73 having mutually different depths h1 and h2, it is possible to cope with a different number of bonding wires 34 that are to be bonded together. For example, when the number of bonding wires 34 to be bonded changes, the bonding tool 90 may be turned 90° clockwise or counterclockwise in FIG. 9B to select the groove 72 or 73 with the appropriate depth h1 or h2 for the number of bonding wires 34. The depths h1 and h2 and opening angles φ1 and φ2 of openings of the grooves 72 and 73 may be appropriately selected depending on the conditions of the bonding targets. The bonding accuracy may be improved by changing the depths h1 and h2 of the grooves 72 and 73 with an inclination.

Depending on the design of the semiconductor chip 32, one or a plurality of bonding wires 34 may be provided on corresponding pads 33 along one edge part on the integrated circuit surface 41. The bonding tool 70 may be used if each semiconductor chip 32 of the completed stacked chip structure 62 has one bonding wire 34 on the pad 33 along one edge part on the integrated circuit surface 41 thereof. On the other hand, if each semiconductor chip 32 of the completed stacked chip structure 62 has a plurality of bonding wires 34 on the corresponding pads 33 along one edge part on the integrated circuit surface 41 thereof, the bonding tool 70 may be modified to include a plurality of grooves 72 and a plurality of grooves 73, respectively corresponding to the number of bonding wires 34 provided along one edge part on the integrated circuit surface 41 of each semiconductor chip 32. In this case, a bonding tool having the grooves 72 arranged in a comb shape in the side view of FIG. 9C and the grooves 73 arranged in a comb shape in the side view of FIG. 9D may be used to simultaneously bond the plurality of bonding wires 34 of each semiconductor chip 32 with the corresponding bonding wires 34 of the other semiconductor chips 32 belonging to the same completed stacked chip structure 62.

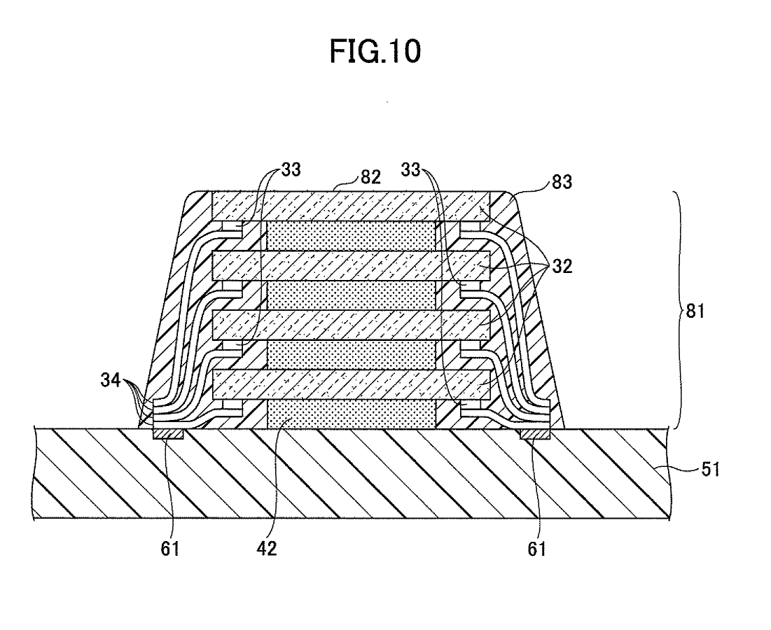

FIG. 10 is a cross sectional view, on an enlarged scale, for explaining a state where a resin encapsulation is carried out with respect to the completed stacked chip structure 62. FIG. 10 illustrates the state where a portion or all of the completed stacked chip structure 62, the bonding wires 34 connected to the connection terminals 61, and the wiring board 51 illustrated in FIG. 7 is subjected to the resin encapsulation to obtain an encapsulated stacked chip structure 81 that is encapsulated by an encapsulating resin 83.

In the step S104, the resin encapsulation is carried out using methods using a transfer mold, potting and the like. In the example illustrated in FIG. 10, a surface 82 of the uppermost semiconductor chip 32 opposite to the integrated circuit surface 41 thereof is exposed from the encapsulating resin 83 in order to enhance heat discharge from the semiconductor chip 32, and the bonding wires 34 are completely encapsulated by the encapsulating resin 83. However, depending on the conditions under which the semiconductor device is used, it is possible to encapsulate the surface 82 of the uppermost semiconductor chip 32 by the encapsulating resin 83 or, to employ other forms of encapsulation.

Of course, the encapsulating resin 83 may be provided at limited portions of the bonding wires 34 in order not to interfere with the free movement of the bonding wires 34 that occur when the bonding wires 34 absorb the internal stress described above.

According to this first embodiment, it is possible to minimize the lengths of the bonding wires connected to each semiconductor chip forming the stacked chip structure. In addition, the stacked chip structure and the wiring board may be electrically connected by the bonding wires, without having to use a conductive (or conductor) paste or the like. For this reason, compared to the conventional stacked semiconductor device, the electrical characteristics of the semiconductor device fabricated by this first embodiment, including the inductance of the stacked chip structure, are greatly improved.

In addition, the bonding wire has a curved shape, including a wave shape, so that an intermediate part of the bonding wire between the end that connects to the semiconductor chip and the end that connects to the connection terminal is non-linear. This curved shape of the bonding wire enables the internal stress generated between the semiconductor chip and the wiring board to be resiliently absorbed by the bonding wire. Accordingly, even in a case where the thermal expansion of the semiconductor chip and the thermal expansion of the wiring board caused by the heating or the like of the integrated circuit within the semiconductor chip are different, it is possible to prevent the generation of an internal stress that would otherwise be generated if the pads on the semiconductor chip were fixed to the wiring board, to thereby improve the mechanical characteristics of the semiconductor device fabricated by this first embodiment, including the mechanical strength of the semiconductor device.

In addition, it is possible to simplify the process of forming the stacked chip structure and improve the productivity of the semiconductor device by simultaneously connecting the bonding wires of each of the semiconductor chips on the wiring board.

### Second Embodiment

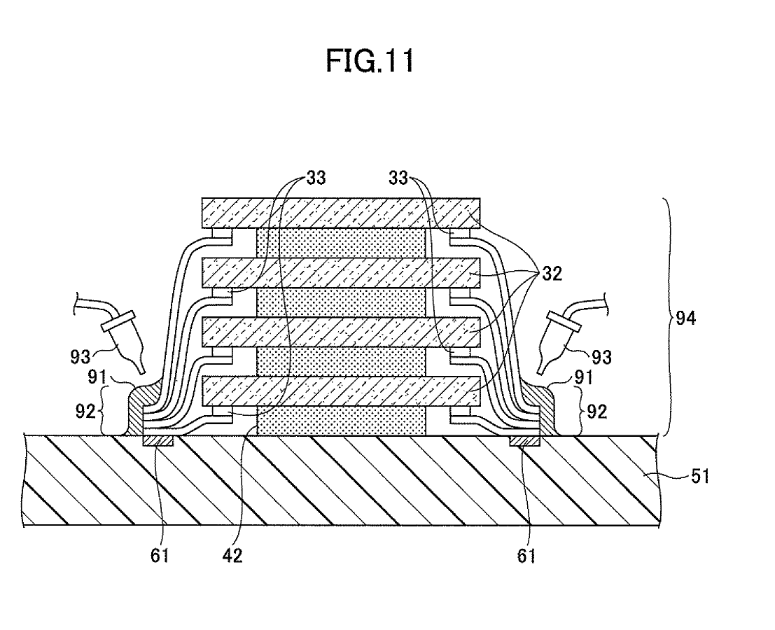

FIG. 11 is a cross sectional view, on an enlarged scale, for explaining the semiconductor device fabrication method in a second embodiment of the present invention. In FIG. 11, those parts that are the same as those corresponding parts in FIG. 10 are designated by the same reference numerals, and a description thereof will be omitted.

This embodiment reinforces (or strengthens) a conductive connecting part 92 by a conductive paste 91. For example, an epoxy resin including a silver (Ag) filler and supplied by syringes 93 may be used for the conductive paste 91. The conductive connecting part 92 of a stacked chip structure 94 may be reinforced with ease by appropriately selecting the viscosity of the conductive paste 91 and supplying droplets thereof coating the conductive paste 91 according to the shape of the conductive connecting part 92.

By applying the conductive paste 91 to the conductive connecting part 92 where the bonding wires 34 of the semiconductor chips 32 are connected to the connection terminals 61 on the wiring board 51, it is possible to reinforce the conductive connecting part 92.

In addition, if the heat discharge from the stacked chip structure 94 is to be enhanced, it is possible to reinforce the conductive connecting part 92 without having to employ a resin encapsulation that would deteriorate the heat discharge effect. Consequently, it is possible to also improve the thermal performance of the stacked chip structure 94.

Of course, the surface of the semiconductor chip 32 opposite to the integrated circuit surface 41 may have a chamfered part (or a sloping part) 321 along at least the edge parts where the bonding wires 34 extend outwards, as described above for the modification of the first embodiment.

### Third Embodiment

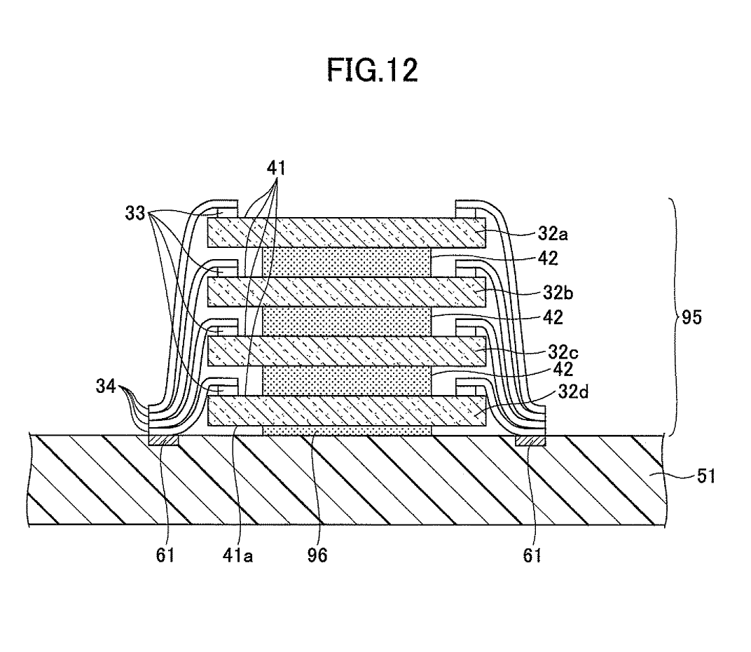

FIG. 12 is a cross sectional view, on an enlarged scale, for explaining the semiconductor device fabrication method in a third embodiment of the present invention. In FIG. 12, those parts that are the same as those corresponding parts in FIG. 10 are designated by the same reference numerals, and a description thereof will be omitted.

This embodiment stacks semiconductor chips 32a, 32b, 32c and 32d in a manner such that the integrated circuit surface 41 of each of the semiconductor chips 32a, 32b, 32c and 32d faces the same direction as the upper surface of the wiring board 51, that is, the integrated circuit surface 41 faces upwards, as illustrated in FIG. 12.

The semiconductor chips 32a, 32b, 32c and 32d may be stacked by the steps S102a and S102b of the first embodiment described above in conjunction with FIG. 2, however, it is unnecessary to provide the insulator resin 44 on the integrated circuit surface 41 of the uppermost semiconductor chip 32a in a stacked chip structure 95. On the other hand, an insulator resin 96 is provided on a lower surface 41a of the lowermost semiconductor chip 32d in the stacked chip structure 95 in order to bond the lowermost semiconductor chip 32d on the wiring board 51. The insulator resin 96 may be made of the same material as the insulator resin 44 or, may be made of a material different from the material forming the insulator resin 44.

Because the integrated circuit surface 41 of each of the semiconductor chips 32a, 32b, 32c and 32d faces up and the semiconductor chips 32a, 32b, 32c and 32d are not turned upside down at the time of the stacking. For example, the insulator resin 96 may be formed by a die bonding paste, such as an epoxy die bonding paste that includes an alumina filler, for example.

No bonding wire is provided between the lower surface 41a of the lowermost semiconductor chip 32d in the stacked chip structure 95 and the upper surface of the wiring board 51 in a vicinity of the insulator resin 96, since the integrated circuit surface 41 of each of the semiconductor chips 32a, 32b, 32c and 32d faces up. Hence, the insulator resin 96 does not require the function of a spacer for the bonding wire, and the thickness of the insulator resin 96 may be relatively thin compared to that of the insulator resin 42. As a result, the stacked chip structure 95 as a whole may be made relatively thin compared to the stacked chip structures 81 and 94.

Because the pad 33 is relatively thin, the bonding wire 34 connected to the pad 33 may make contact with the edge part of each of the semiconductor chips 32a, 32b, 32c and 32d to which the bonding wire 34 belongs, when being bent towards the wiring board 51. Accordingly, it is preferable to shape the bonding wire 34 in the wave shape as described above in conjunction with FIGS. 4A through 4D in order to avoid the contact between the bonding wire 34 and the edge part of the corresponding one of the semiconductor chips 32a, 32b, 32c and 32d.

The contact between the bonding wire and the surface or the edge part of the semiconductor chip does not introduce problems if a separate step (or process) is carried out to protect and insulate the surface or the edge part of the semiconductor chip by forming thereon an insulator layer made of silicon dioxide (SiO₂) or the like, for example. In this case, it is possible to prevent the reliability of the semiconductor device from deteriorating.

According to this embodiment, the gap between the lowermost semiconductor chip in the stacked chip structure and the wiring board can be reduced, to thereby enable the thickness of the stacked chip structure as a whole to be reduced. As a result, the stacked chip structure may be made compact, and it is possible to improve the reliability of the semiconductor device that has the reduced size.

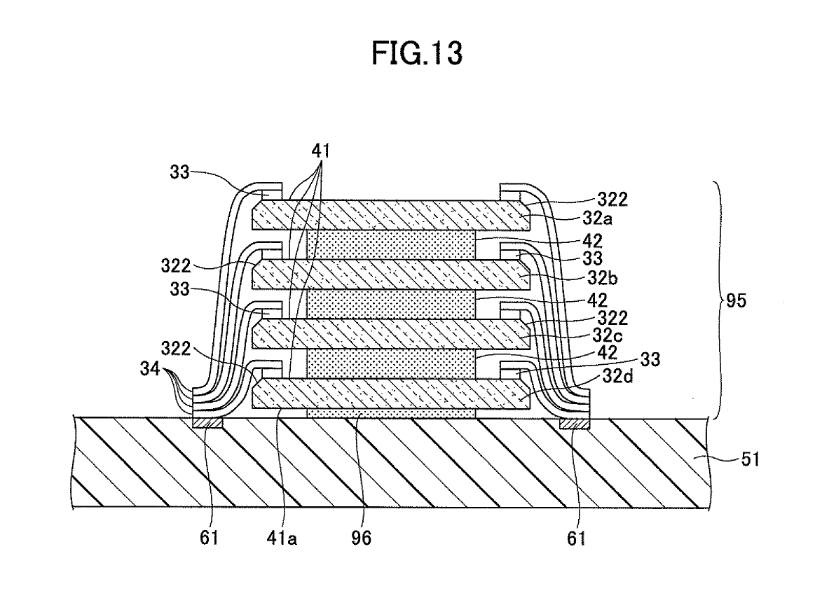

FIG. 13 is a cross sectional view, on an enlarged scale, for explaining the semiconductor device fabrication method in a modification of the third embodiment. In FIG. 13, those parts that are the same as those corresponding parts in FIG. 12 are designated by the same reference numerals, and a description thereof will be omitted.

In this modification, the integrated circuit surface 41 of each of the semiconductor chips 32a, 32b, 32c and 32d has a chamfered part (or a sloping part) 322 along at least the edge parts where the bonding wires 34 extend outwards, as illustrated in FIG. 13. In other words, the chamfered part 322 is provided along at least the edge part of the integrated circuit surface 41. For example, the bonding wire 34 extending generally downwards from the uppermost semiconductor chip 32a in FIG. 13 has a sufficient clearance from the integrated circuit surface 41 and the edge part of the semiconductor chip 32b located immediately below, due to the provision of the chamfered part 322. As a result, it is possible to more positively prevent the bonding wire 34 from making contact with the integrated circuit surface 41 or the edge part of each of the semiconductor chips 32a, 32b, 32c and 32d. For example, the chamfered part 322 may be formed when dicing the semiconductor wafer into the semiconductor chips 32a, 32b, 32c and 32d by carrying out a bevel cutting process using a dicing apparatus (not illustrated).

Further, the chamfered part 322 may be replaced by a rounded part.

### Fourth Embodiment

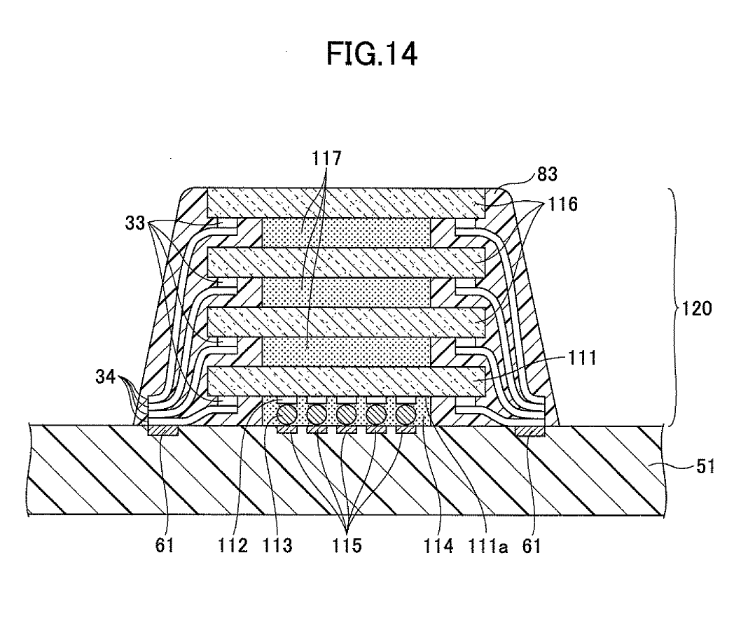

FIG. 14 is a cross sectional view, on an enlarged scale, for explaining the semiconductor device fabrication method in a fourth embodiment of the present invention. In FIG. 14, those parts that are the same as those corresponding parts in FIG. 10 are designated by the same reference numerals, and a description thereof will be omitted.

Bumps 113 are formed on pads 112 on an integrated circuit surface 111a of a lowermost semiconductor chip 111 in a stacked chip structure 120, and lower ends of the bumps 113 in FIG. 14 (that is, top ends of the bumps 113 before the lowermost semiconductor chip 111 is turned upside down) are exposed from an insulator resin 114 that is coated on the integrated circuit surface 111a of the lowermost semiconductor chip 111.

The bumps 113 may be formed by ball bonding using bonding wires or, by ball bump transfer that transfers each independently formed ball. The bumps 113 on the lowermost semiconductor chip 111 may be bonded on connection terminals 115 on the wiring board 51 by flip-chip bonding, by coating on the connection terminals a solder that includes tin (Sn), silver (Ag) or the like. In other words, the pads 112 on the integrated circuit surface 111a of the lowermost semiconductor chip 111 are electrically connected to the connecting terminals 115 by the bumps 113 that are conductive connecting members other the bonding wires 34.

Three (3) semiconductor chips 116 are stacked via insulator resins 117, and provided on a surface of the lowermost semiconductor chip 111 opposite to the integrated circuit surface 111a. The bonding wires 34 connected to the pads 33 of the semiconductor chips 111 and 116 are connected to the connection terminals 61 on the wiring board 51. The stacked chip structure 120 is encapsulated by the resin 83 depending on the environment in which the semiconductor device is used.

The processes other than the flip-chip bonding process may be carried out similarly to the corresponding processes of the first embodiment described above.

According to this embodiment, it is possible to form a stacked chip structure in which memories and logic circuits of a Known Good Die (KGD) are combined. Consequently, the application of the semiconductor chips to the stacked chip structure may be improved when designing semiconductor packages. The performance of the semiconductor device may be improved because the stacked chip structure may be made compact.

Of course, the surface of the semiconductor chip 116 opposite to the integrated circuit surface may have a chamfered part (or a sloping part) 321 along at least the edge parts where the bonding wires 34 extend outwards, as described above for the modification of the first embodiment.

### Fifth Embodiment

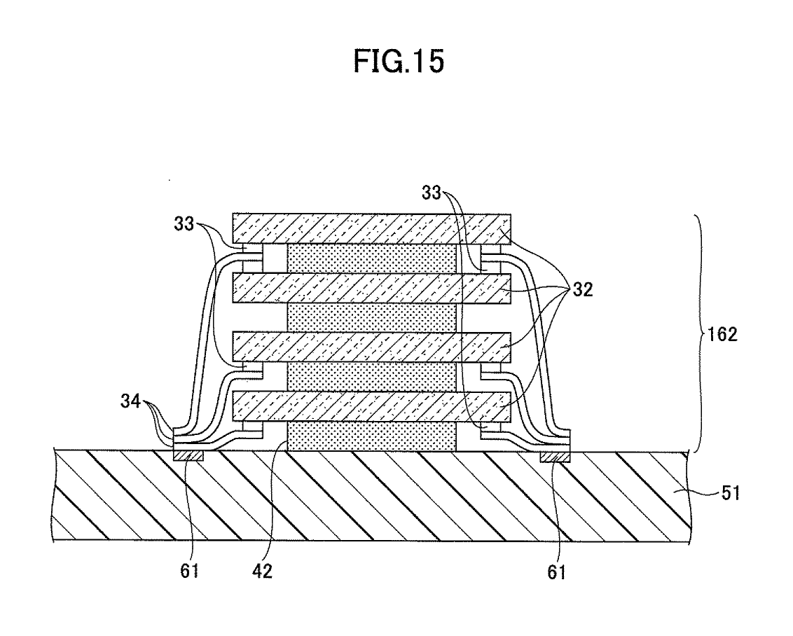

FIG. 15 is a cross sectional view, on an enlarged scale, for explaining a state where ends of the bonding wires of the stacked semiconductor chips are connected on the wiring board in a fifth embodiment of the present invention. In FIG. 15, those parts that are the same as those corresponding parts in FIG. 7 are designated by the same reference numerals, and a description thereof will be omitted.

In the first, second and fourth embodiments and the modification thereof described above, the integrated circuit surface of each of the semiconductor chips forming the stacked chip structure face the mounting surface of the wiring board. However, the semiconductor chips in the stacked chip structure may include semiconductor chips having the integrated circuit surfaces thereof facing the mounting surface of the wiring board, and at least one pair of semiconductor chips having the integrated circuit surfaces thereof facing each other.

FIG. 15 illustrates an example where the uppermost and the second uppermost semiconductor chips 32 are stacked so that the integrated circuit surfaces 41 thereof face each other in a stacked chip structure 162. In this example, a pair of mutually opposing pads 33 of the uppermost and the second uppermost semiconductor chips 32 sandwich a single bonding wire 34. Hence, when stacking the semiconductor chips 32 to form the stacked chip structure 162, only one of each pair of mutually opposing pads 33 of the uppermost and the second uppermost semiconductor chips 32 needs to have the bonding wire 34 bonded thereon. For example, when stacking the semiconductor chips 32 to form the stacked chip structure 162, one of the uppermost and the second uppermost semiconductor chips 32 does not require the bonding wire 34 to be bonded on the pad 33 thereof, and the second uppermost semiconductor chip 32 is stacked in an orientation opposite to the orientation of the other semiconductor chips 32 in the stacked chip structure 162.

Of course, the number of semiconductor chips 32 in the stacked chip structure 162 is not limited to that illustrated in FIG. 15. Further, at least the second uppermost semiconductor chip 32 and the lowermost semiconductor chip 32 in the stacked chip structure 162 illustrated in FIG. 15 may be provided with a chamfered part along at least the edge part of the surface opposite to the integrated circuit surface 41 where the pads 33 are provided.

According to this embodiment, the number of bonding wires 34 may be reduced to simplify the structure and to simplify the process of electrically connecting (or bonding) the ends of the bonding wires 34 to the corresponding connection terminals 61 on the wiring board 51 by the thermo-compression bonding or the like using the wire bonding apparatus, for example.

In addition, when a resin encapsulation is carried out with respect to the stacked chip structure 162 illustrated in FIG. 15 in order to encapsulate at least the stacked chip structure 162, it is not essential to provide the insulator resin 42 between the integrated circuit surfaces 41 of the uppermost and the second uppermost semiconductor chips 32, because the encapsulating resin 83 will fill the gap between the integrated circuit surfaces 41 of the uppermost and the second uppermost semiconductor chips 32 in the state where the gap is maintained by the spacing provided by the pair of mutually opposing pads 33 of the uppermost and the second uppermost semiconductor chips 32 sandwiching the bonding wire 34.

Effects similar to the effects obtainable by this fifth embodiment may be obtained by applying the structure of this fifth embodiment to the structure of any of the second and fourth embodiments and the modification thereof described above.

### Sixth Embodiment

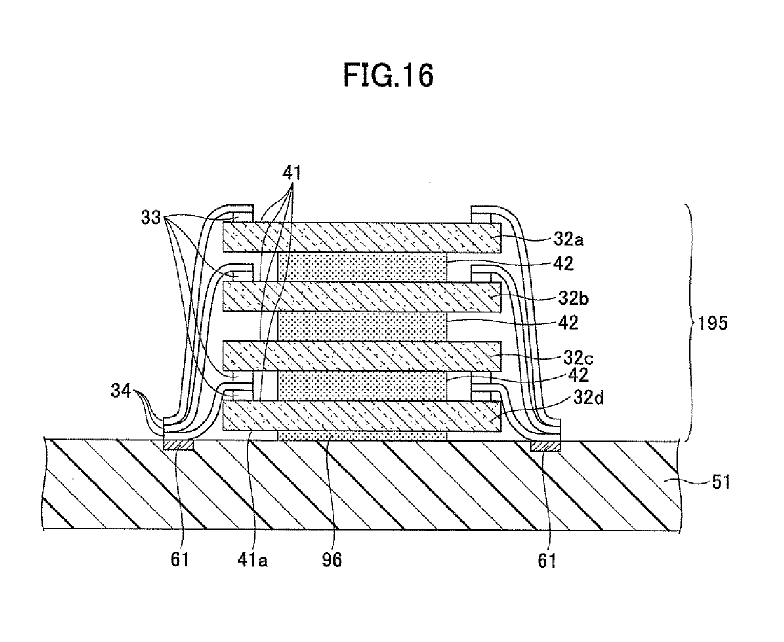

FIG. 16 is a cross sectional view, on an enlarged scale, for explaining the semiconductor device fabrication method in a sixth embodiment of the present invention. In FIG. 16, those parts that are the same as those corresponding parts in FIG. 12 are designated by the same reference numerals, and a description thereof will be omitted.

In the third embodiment and the modification thereof described above, the integrated circuit surface of each of the semiconductor chips forming the stacked chip structure face a direction opposite to the mounting surface of the wiring board. However, the semiconductor chips in the stacked chip structure may include semiconductor chips having the integrated circuit surfaces thereof facing the direction opposite to the mounting surface of the wiring board, and at least one pair of semiconductor chips having the integrated circuit surfaces thereof facing each other.

FIG. 16 illustrates an example where the lowermost and the second lowermost semiconductor chips 32 are stacked so that the integrated circuit surfaces 41 thereof face each other in a stacked chip structure 195. In this example, a pair of mutually opposing pads 33 of the lowermost and the second lowermost semiconductor chips 32 sandwich a single bonding wire 34. Hence, when stacking the semiconductor chips 32 to form the stacked chip structure 195, only one of each pair of mutually opposing pads 33 of the lowermost and the second lowermost semiconductor chips 32 needs to have the bonding wire 34 bonded thereon. For example, when stacking the semiconductor chips 32 to form the stacked chip structure 195, one of the lowermost and the second lowermost semiconductor chips 32 does not require the bonding wire 34 to be bonded on the pad 33 thereof, and the second lowermost semiconductor chip 32 is stacked in an orientation opposite to the orientation of the other semiconductor chips 32 in the stacked chip structure 195.

Of course, the number of semiconductor chips 32 in the stacked chip structure 195 is not limited to that illustrated in FIG. 16. Further, at least the uppermost, the second uppermost and the lowermost semiconductor chips 32 in the stacked chip structure 195 illustrated in FIG. 16 may be provided with a chamfered part 322 along at least the edge part of the integrated circuit surface 41 where the pads 33 are provided.

According to this embodiment, the number of bonding wires 34 may be reduced to simplify the structure and to simplify the process of electrically connecting (or bonding) the ends of the bonding wires 34 to the corresponding connection terminals 61 on the wiring board 51 by the thermo-compression bonding or the like using the wire bonding apparatus, for example.

In addition, when a resin encapsulation is carried out with respect to the stacked chip structure 195 illustrated in FIG. 16 in order to encapsulate at least the stacked chip structure 195, it is not essential to provide the insulator resin 42 between the integrated circuit surfaces 41 of the lowermost and the second lowermost semiconductor chips 32, because the encapsulating resin 83 will fill the gap between the integrated circuit surfaces 41 of the lowermost and the second lowermost semiconductor chips 32 in the state where the gap is maintained by the spacing provided by the pair of mutually opposing pads 33 of the lowermost and the second lowermost semiconductor chips 32 sandwiching the bonding wire 34.

Effects similar to the effects obtainable by this sixth embodiment may be obtained by applying the structure of this sixth embodiment to the structure of any of the third embodiment and the modification thereof described above.

In the fifth and sixth embodiments described above, the at least one pair of semiconductor chips having the integrated circuit surfaces thereof facing each other may be provided at an arbitrary position in the stacked chip structure.

Further, the present invention is not limited to these embodiments, but various variations and modifications may be made without departing from the scope of the present invention.

What is claimed is:

1. A semiconductor device comprising:
a board having a mounting surface and a plurality of connection terminals provided on the mounting surface; and
a stacked chip structure provided on the board and including a plurality of semiconductor chips that are stacked via insulators,
wherein the semiconductor chips in the stacked chip structure include semiconductor chips comprising:
an integrated circuit surface;
a plurality of pads provided on the integrated circuit surface along at least one edge part of the integrated circuit surface; and
a plurality of conductive connecting members having a wave shape with first ends electrically connected to the pads, and second ends extending outwardly from the at least one edge part and electrically connected to the connection terminals on the board,
wherein the conductive connecting members of at least one of the semiconductor chips have a length different from that of the conductive connecting members of another semiconductor chip in the stacked chip structure, and
the conductive connecting members are formed by bonding wires, and the second ends of the conductive connecting members extending from the semiconductor chips in the stacked chip structure are aligned on the connection terminals on the board.

2. The semiconductor device as claimed in claim 1, wherein the integrated circuit surface of each of the semiconductor chips in the stacked chip structure face the mounting surface of the board.

3. The semiconductor device as claimed in claim 2, wherein each of the semiconductor chips comprises:
a surface opposite to the integrated circuit surface; and
a chamfered part provided along at least one edge part of the surface opposite to the integrated circuit surface.

4. The semiconductor device as claimed in claim 2, wherein:
the board further has second connecting terminals provided on the mounting surface;
a lowermost semiconductor chip in the stacked chip structure comprises a plurality of second pads; and
the second pads and the second connection terminals are electrically connected by bumps that are other than the conductive connecting members.

5. The semiconductor device as claimed in claim 1, wherein the semiconductor chips in the stacked chip structure include semiconductor chips having the integrated circuit surfaces thereof facing the mounting surface of the board, and at least one pair of semiconductor chips having the integrated circuit surfaces thereof facing each other.

6. The semiconductor device as claimed in claim 1, wherein the integrated circuit surface of each of the semiconductor chips in the stacked chip structure faces a direction opposite to the mounting surface of the board.

7. The semiconductor device as claimed in claim 6, wherein each of the semiconductor chips comprises:
a chamfered part provided along the at least one edge part of the integrated circuit surface.

8. The semiconductor device as claimed in claim 1, wherein the semiconductor chips in the stacked chip structure include semiconductor chips having the integrated circuit surfaces thereof facing a direction opposite to the mounting surface of the board, and at least one pair of semiconductor chips having the integrated circuit surfaces thereof facing each other.

9. A semiconductor device fabrication method comprising:
electrically connecting first ends of conductive connecting members on pads on a semiconductor chip;
stacking a plurality of semiconductor chips via insulators to form a stacked chip structure; and
mounting the stacked chip structure on a mounting surface of a board by electrically connecting second ends of the conductive connecting members to connection terminals on the mounting surface,
wherein the conductive connecting members have a wave shape,
the conductive connecting members of at least one of the semiconductor chips have a length different from that of the conductive connecting members of another semiconductor chip in the stacked chip structure, and
the conductive connecting members are formed by bonding wires, and said mounting aligns the second ends of the conductive connecting members extending from the semiconductor chips in the stacked chip structure on the connection terminals on the board.

10. The semiconductor device fabrication method as claimed in claim 9, wherein said stacking stacks the semiconductor chips so that an integrated circuit surface of each of the semiconductor chips in the stacked chip structure face the mounting surface of the board.

11. The semiconductor device fabrication method as claimed in claim 10, wherein each of the semiconductor chips comprises a surface opposite to the integrated circuit surface, and a chamfered part provided along at least one edge part of the surface opposite to the integrated circuit surface.

12. The semiconductor device fabrication method as claimed in claim 10, wherein the board further has second connecting terminals provided on the mounting surface, and said mounting electrically connects second pads of a lowermost semiconductor chip in the stacked chip structure and second connection terminals on the mounting surface of the board by bumps that are other than the conductive connecting members.

13. The semiconductor device fabrication method as claimed in claim 9, wherein said stacking stacks the semiconductor chips so that the stacked chip structure includes semiconductor chips having the integrated circuit surfaces thereof facing the mounting surface of the board, and at least one pair of semiconductor chips having the integrated circuit surfaces thereof facing each other.

14. The semiconductor device fabrication method as claimed in claim 9, wherein said stacking stacks the semiconductor chips so that an integrated circuit surface of each of the semiconductor chips in the stacked chip structure faces a direction opposite to the mounting surface of the board.

15. The semiconductor device fabrication method as claimed in claim 14, wherein each of the semiconductor chips comprises a chamfered part provided along the at least one edge part of the integrated circuit surface.

16. The semiconductor device fabrication method as claimed in claim 10, wherein said mounting electrically connects the second ends of the conductive connecting members to the connection terminals by a conductive paste.

17. The semiconductor device fabrication method as claimed in claim 10, further comprising:
encapsulating at least the conductive connecting members by an encapsulating resin.

18. The semiconductor device fabrication method as claimed in claim 17, wherein said encapsulating exposes an upper surface of an uppermost semiconductor chip in the stacked chip structure.

19. The semiconductor device fabrication method as claimed in claim 9, wherein said stacking stacks the semiconductor chips so that the stacked chip structure includes semiconductor chips having the integrated circuit surfaces thereof facing a direction opposite to the mounting surface of the board, and at least one pair of semiconductor chips having the integrated circuit surfaces thereof facing each other.
